(19) United States
(12) Patent Application Publication
(10) Pub. No.: US 2026/0082610 A1
(43) Pub. Date: Mar. 19, 2026

(54) SEMICONDUCTOR DEVICE STRUCTURE AND METHODS OF FORMING THE SAME

(71) Applicant: TAIWAN SEMICONDUCTOR MANUFACTURING COMPANY, LTD., Hsinchu (TW)

(72) Inventors: Kuei-Yu KAO, Hsinchu (TW); Ting-Wen SHIH, Hsinchu (TW); Chiung-Yu CHO, Hsinchu (TW)

(21) Appl. No.: 19/010,011

(22) Filed: Jan. 5, 2025

Related U.S. Application Data
(60) Provisional application No. 63/695,042, filed on Sep. 16, 2024.

(51) Int. Cl. H10D 30/01; H01L 21/02; H10D 30/00; H10D 64/23

(52) U.S. Cl. CPC H10D 30/0196; H10D 30/509; H10P 14/6339; H10D 64/258

(57) ABSTRACT

A semiconductor device structure and methods of forming the same are described. The method includes forming a fin structure over a substrate and depositing one or more spacers on a portion of the fin structure. The one or more spacers are deposited on sidewalls of the fin structure. The method further includes removing a first portion of the one or more spacers to expose the fin structure and recessing the fin structure. A first byproduct layer is formed on a second portion of the one or more spacers. The method further includes passivating the first byproduct layer, softening the first byproduct layer, removing a portion of the first byproduct layer to expose the recessed fin structure, and further recessing the fin structure.

### CROSS-REFERENCE TO RELATED APPLICATIONS

This application claims priority to U.S. Provisional Application Ser. No. 63/695,042 filed Sep. 16, 2024, which is incorporated by reference in its entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

Therefore, there is a need to improve processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 2, 3, 4, and 5 are perspective views of various stages of manufacturing a semiconductor device structure, in accordance with some embodiments.

FIG. 6A is a perspective view of one of various stages of manufacturing the semiconductor device structure, in accordance with some embodiments.

FIG. 6B is a cross-sectional side view of one of various stages of manufacturing the semiconductor device structure taken along line A-A of FIG. 5, in accordance with some embodiments.

FIGS. 7A, 7B, 7C, 7D, 7E, and 7F are cross-sectional side views of various stages of manufacturing the semiconductor device structure taken along line A-A of FIG. 5, in accordance with some embodiments.

FIGS. 8A, 9A, 10A, and 11A are perspective views of various stages of manufacturing the semiconductor device structure, in accordance with some embodiments.

FIGS. 8B, 9B, 10B, and 11B are cross-sectional side views of various stages of manufacturing the semiconductor device structure taken along line A-A of FIG. 5, in accordance with some embodiments.

FIGS. 8C, 9C, 10C, and 11C are cross-sectional side views of various stages of manufacturing the semiconductor device structure taken along line B-B of FIG. 5, in accordance with some embodiments.

FIGS. 12, 13, and 14 are cross-sectional side views of various stages of manufacturing the semiconductor device structure taken along line B-B of FIG. 5, in accordance with some embodiments.

FIGS. 15A, 16A, 17A, 18A, and 19A are perspective views of various stages of manufacturing the semiconductor device structure, in accordance with alternative embodiments.

FIGS. 15B, 16B, 17B, 18B, and 19B are cross-sectional side views of various stages of manufacturing the semiconductor device structure taken along line A-A of FIG. 5, in accordance with alternative embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

While the embodiments of this disclosure are discussed with respect to nanostructure channel FETs, such as gate all around (GAA) FETs, for example Horizontal Gate All Around (HGAA) FETs or Vertical Gate All Around (VGAA) FETs, implementations of some aspects of the present disclosure may be used in other processes and/or in other devices, such as planar FETs, Fin-FETs, and other suitable devices. A person having ordinary skill in the art will readily understand other modifications that may be made are contemplated within the scope of this disclosure. In cases where gate all around (GAA) transistor structures are adapted, the GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

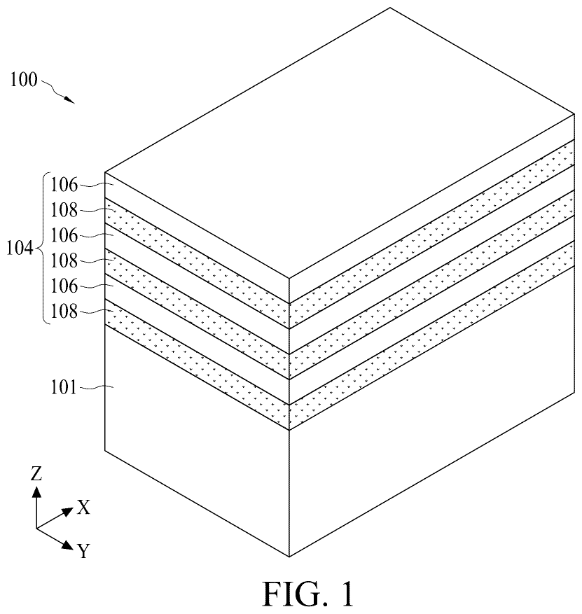

FIGS. 1-14 show exemplary processes for manufacturing a semiconductor device structure 100 according to embodiments of the present disclosure. It is understood that additional operations can be provided before, during, and after processes shown by FIGS. 1-14, and some of the operations described below can be replaced or eliminated, for additional embodiments of the method. The order of the operations/processes is not limiting and may be interchangeable.

FIGS. 1, 2, 3, 4, and 5 are perspective views of various stages of manufacturing a semiconductor device structure 100, in accordance with some embodiments. As shown in FIG. 1, a semiconductor device structure 100 includes a stack of semiconductor layers 104 formed over a front side of a substrate 101. The substrate 101 may be a semiconductor substrate. The substrate 101 may include a crystalline semiconductor material such as, but not limited to silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb) and indium phosphide (InP).

The substrate 101 may include various regions that have been doped with impurities (e.g., dopants having p-type or n-type conductivity). Depending on circuit design, the dopants may be, for example phosphorus for an n-type field effect transistors (NFET) and boron for a p-type field effect transistors (PFET).

The stack of semiconductor layers 104 includes alternating semiconductor layers made of different materials to facilitate formation of nanostructure channels in a multi-gate device, such as nanostructure channel FETs. In some embodiments, the stack of semiconductor layers 104 includes first semiconductor layers 106 and second semiconductor layers 108. In some embodiments, the stack of semiconductor layers 104 includes alternating first and second semiconductor layers 106, 108. The first semiconductor layers 106 and the second semiconductor layers 108 are made of semiconductor materials having different etch selectivity and/or oxidation rates. For example, the first semiconductor layers 106 may be made of Si and the second semiconductor layers 108 may be made of SiGe. In some examples, the first semiconductor layers 106 may be made of SiGe and the second semiconductor layers 108 may be made of Si. Alternatively, in some embodiments, either of the semiconductor layers 106, 108 may be or include other materials such as Ge, SiC, GaAs, GaP, InP, InAs, InSb, GaAsP, AlInAs, AlGaAs, InGaAs, GaInP, GaInAsP, or any combinations thereof.

The first and second semiconductor layers 106, 108 are formed by any suitable deposition process, such as epitaxy. By way of example, epitaxial growth of the layers of the stack of semiconductor layers 104 may be performed by a molecular beam cpitaxy (MBE) process, a metalorganic chemical vapor deposition (MOCVD) process, and/or other suitable epitaxial growth processes.

The first semiconductor layers 106 or portions thereof may form nanostructure channel(s) of the semiconductor device structure 100 in later fabrication stages. The term nanostructure is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including, for example, a cylindrical in shape or substantially rectangular cross-section. The nanostructure channel(s) of the semiconductor device structure 100 may be surrounded by a gate electrode. The semiconductor device structure 100 may include a nanostructure transistor. The nanostructure transistors may be referred to as nanosheet transistors, nanowire transistors, gate-all-around (GAA) transistors, multi-bridge channel (MBC) transistors, or any transistors having the gate electrode surrounding the channels. The use of the first semiconductor layers 106 to define a channel or channels of the semiconductor device structure 100 is further discussed below.

Each first semiconductor layer 106 may have a thickness in a range between about 5 nm and about 30 nm. Each second semiconductor layer 108 may have a thickness that is equal, less, or greater than the thickness of the first semiconductor layer 106. In some embodiments, each second semiconductor layer 108 has a thickness in a range between about 2 nm and about 50 nm. Three first semiconductor layers 106 and three second semiconductor layers 108 are alternately arranged as illustrated in FIG. 1, which is for illustrative purposes and not intended to be limiting beyond what is specifically recited in the claims. It can be appreciated that any number of first and second semiconductor layers 106, 108 can be formed in the stack of semiconductor layers 104, and the number of layers depending on the predetermined number of channels for the semiconductor device structure 100. In some embodiments, the stack of semiconductor layers 104 includes two first semiconductor layers 106. In some embodiments, the stack of semiconductor layers 104 includes three first semiconductor layers 106. In some embodiments, the stack of semiconductor layers 104 includes four first semiconductor layers 106.

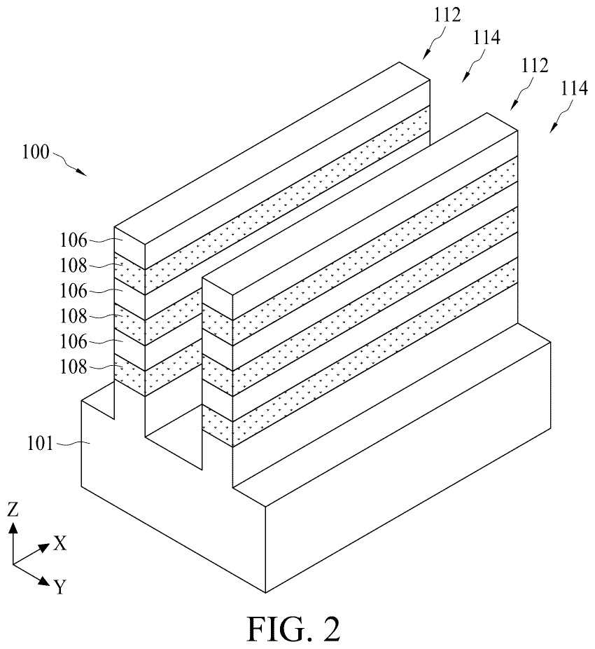

As shown in FIG. 2, fin structures 112 are formed from the stack of semiconductor layers 104. Each fin structure 112 has an upper portion including the semiconductor layers 106, 108 and a substrate portion 116 formed from the substrate 101. The fin structures 112 may be formed by patterning a hard mask layer (not shown) formed on the stack of semiconductor layers 104 using multi-patterning operations including photo-lithography and etching processes. The etching process can include dry etching, wet etching, reactive ion etching (RIE), and/or other suitable processes. The photo-lithography process may include forming a photoresist layer (not shown) over the hard mask layer, exposing the photoresist layer to a pattern, performing post-exposure bake processes, and developing the photoresist layer to form a masking element including the photoresist layer. In some embodiments, patterning the photoresist layer to form the masking element may be performed using an electron beam (e-beam) lithography process. The etching process forms trenches 114 in unprotected regions through the hard mask layer, through the stack of semiconductor layers 104, and into the substrate 101, thereby leaving the plurality of extending fin structures 112. The trenches 114 extend along the X direction. The trenches 114 may be etched using a dry etch (e.g., RIE), a wet etch, and/or combination thereof.

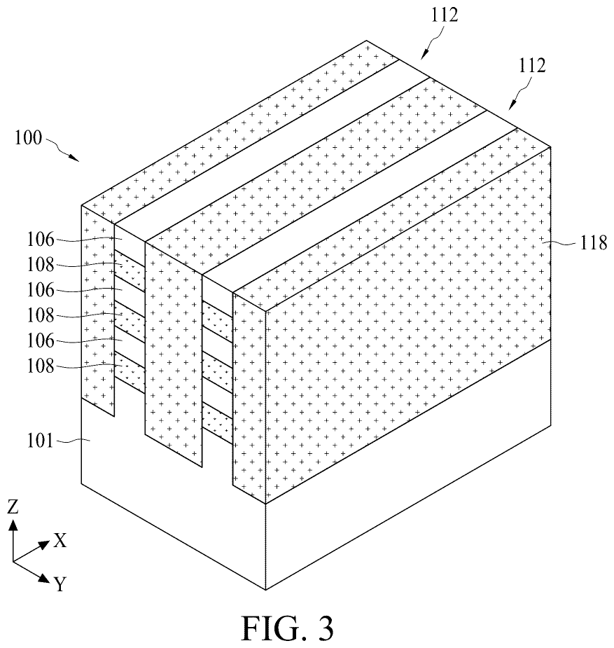

As shown in FIG. 3, after the fin structures 112 are formed, an insulating material 118 is formed on the substrate 101. The insulating material 118 fills the trenches 114 between neighboring fin structures 112 until the fin structures 112 are embedded in the insulating material 118. Then, a planarization operation, such as a chemical mechanical polishing (CMP) method and/or an etch-back method, is performed such that the top of the fin structures 112 is exposed. The insulating material 118 may be made of silicon oxide, silicon nitride, silicon oxynitride (SiON), SiOCN, SiCN, fluorine-doped silicate glass (FSG), a low-K dielectric material, or any suitable dielectric material. The insulating material 118 may be formed by any suitable method, such as low-pressure chemical vapor deposition (LPCVD), plasma enhanced CVD (PECVD) or flowable CVD (FCVD).

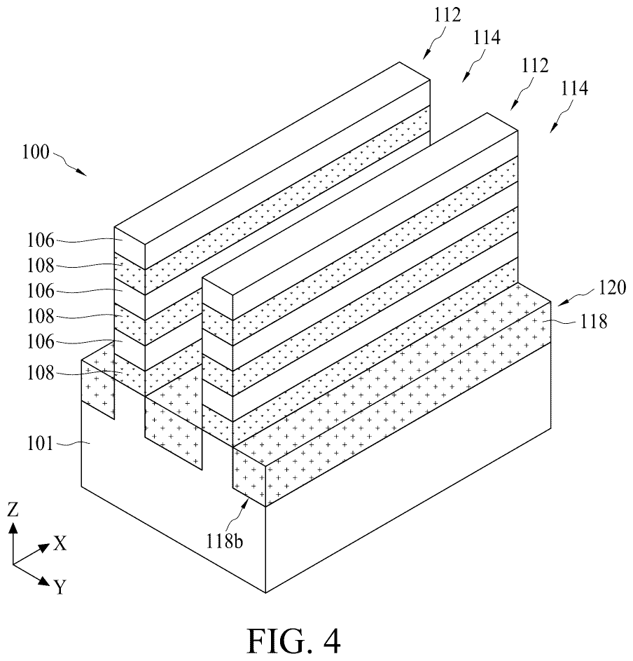

As shown in FIG. 4, the insulating material 118 is recessed to form isolation regions 120. The recess of the insulating material 118 exposes portions of the fin structures 112, such as the stack of semiconductor layers 104. The recess of the insulating material 118 reveals the trenches 114 between the neighboring fin structures 112. The isolation regions 120 may be formed using a suitable process, such as a dry etching process, a wet etching process, or a combination thereof. A top surface of the insulating material 118 may be level with or below a surface of the second semiconductor layers 108 in contact with the substrate portion 116 formed from the substrate 101. In some embodiments, the isolation regions 120 are the shallow trench isolation (STI) regions.

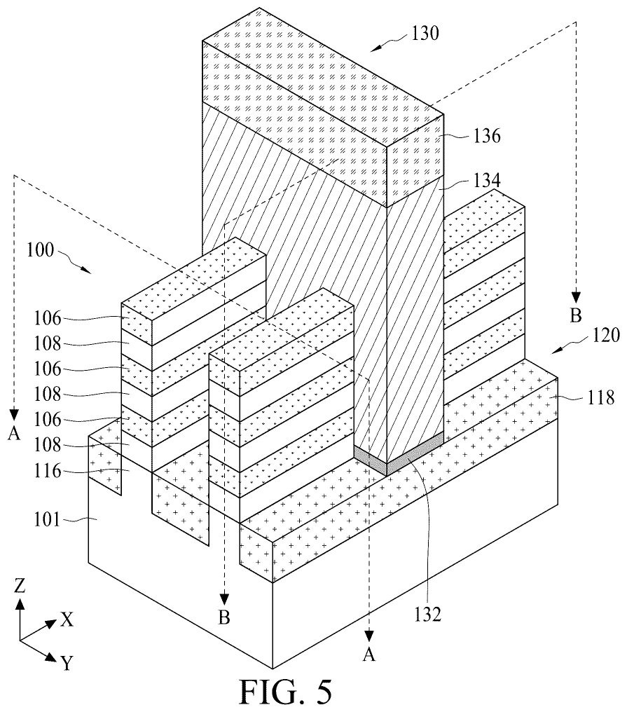

As shown in FIG. 5, one or more sacrificial gate structures 130 (only one is shown) are formed over the semiconductor device structure 100. The sacrificial gate structures 130 are formed over a portion of the fin structures 112. Each sacrificial gate structure 130 may include a sacrificial gate dielectric layer 132, a sacrificial gate electrode layer 134, and a mask layer 136. The sacrificial gate dielectric layer 132, the sacrificial gate electrode layer 134, and the mask layer 136 may be formed by sequentially depositing blanket layers of the sacrificial gate dielectric layer 132, the sacrificial gate electrode layer 134, and the mask layer 136, and then patterning those layers into the sacrificial gate structures 130. While one sacrificial gate structure 130 is shown, two or more sacrificial gate structures 130 may be arranged along the X direction in some embodiments.

The sacrificial gate dielectric layer 132 may include one or more layers of dielectric material, such as a silicon oxide-based material. The sacrificial gate electrode layer 134 may include silicon such as polycrystalline silicon or amorphous silicon. The mask layer 136 may include more than one layer, such as an oxide layer and a nitride layer. The portions of the fin structures 112 that are covered by the sacrificial gate electrode layer 134 of the sacrificial gate structure 130 serve as channel regions for the semiconductor device structure 100.

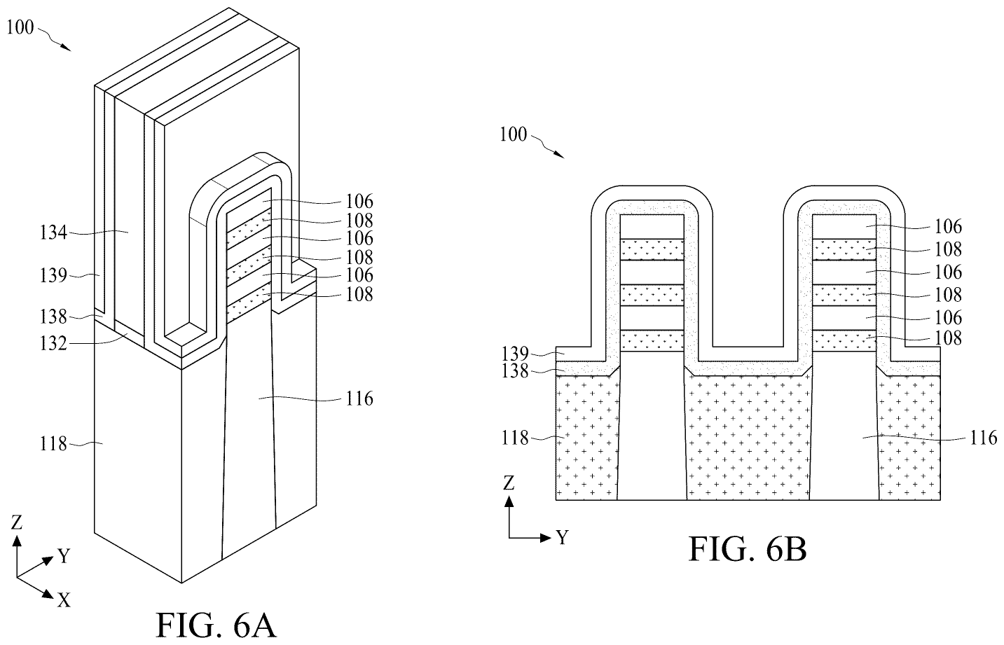

FIG. 6A is a perspective view of one of various stages of manufacturing the semiconductor device structure 100, in accordance with some embodiments. FIG. 6B is a cross-sectional side view of one of various stages of manufacturing the semiconductor device structure 100 taken along line A-A of FIG. 5, in accordance with some embodiments. FIG. 6B is a corresponding cross-sectional view of the semiconductor device structure 100 shown in FIG. 6A. As shown in FIGS. 6A and 6B, first and second spacers 138, 139 are deposited on the exposed surfaces of the semiconductor device structure 100. For example, the first spacer 138 is deposited on the fin structures 112, the isolation regions 120, and the sacrificial gate structure 130, and the second spacer 139 is deposited on the first spacer 138. The first spacer 138 may be made of a dielectric material such as silicon oxide, silicon nitride, silicon carbide, silicon oxynitride, SiCN, silicon oxycarbide, SiCON, and/or combinations thereof. The first spacer 138 may be formed by any suitable process. In some embodiments, the first spacer 138 is a conformal layer formed by a conformal process, such as an atomic layer deposition (ALD) process. In some embodiments, the first spacer 138 includes SiOCN having 30 to 40 atomic percent of Si, 40 to 55 atomic percent of 0, 10 to 20 atomic percent of C, and 1 to 10 atomic percent of N.

The second spacer 139 may include any suitable dielectric material, such as SiOx, SiON, SiN, SiCON, or SiCO. The second spacer 139 may have a thickness ranging from about 0.5 nm to about 5 nm. The second spacer 139 may be formed by any suitable process. In some embodiments, the second spacer 139 is deposited by CVD, PECVD, or electron cyclotron resonance CVD (ECR-CVD). In some embodiments, the second spacer 139 includes SiOCN having 30 to 40 atomic percent of Si, 40 to 55 atomic percent of 0, 10 to 20 atomic percent of C, and 1 to 10 atomic percent of N. In some embodiments, the composition of the second spacer 139 may be different from the composition of the first spacer 138. In some embodiments, a single spacer, such as the first spacer 138, is present, while the second spacer 139 is not present.

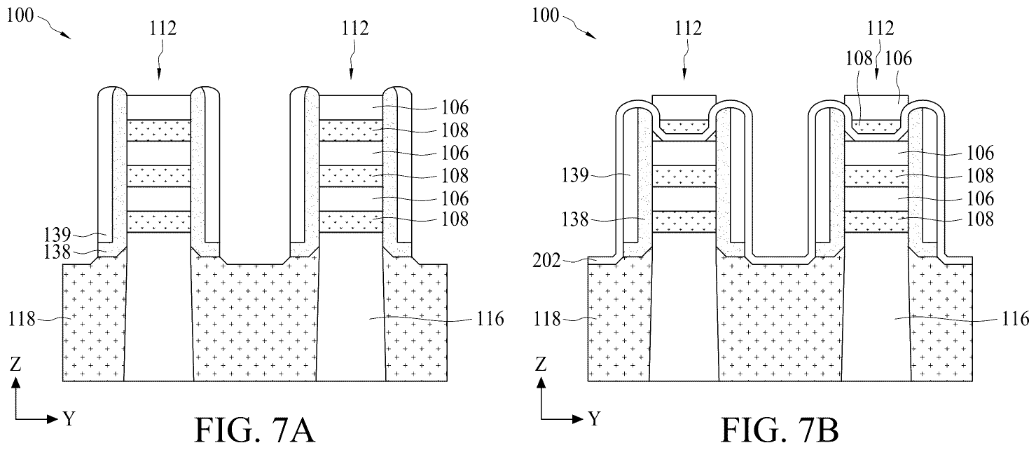

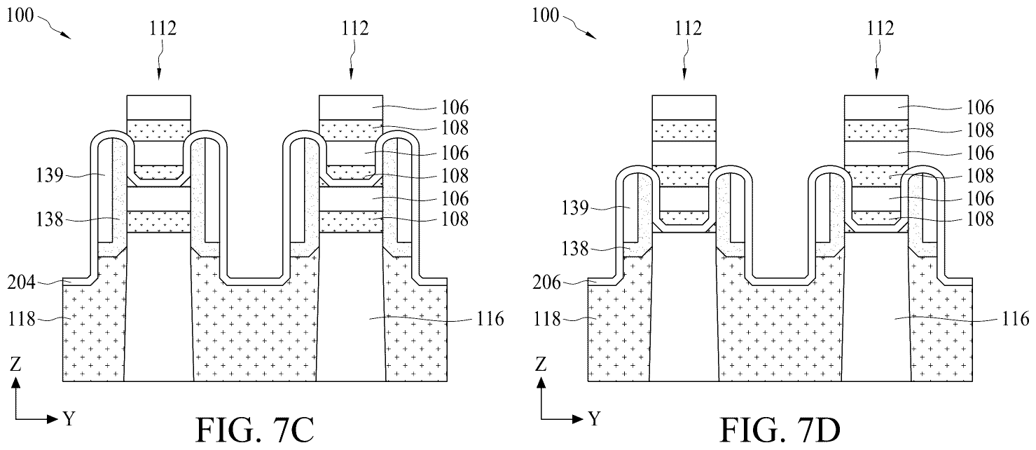

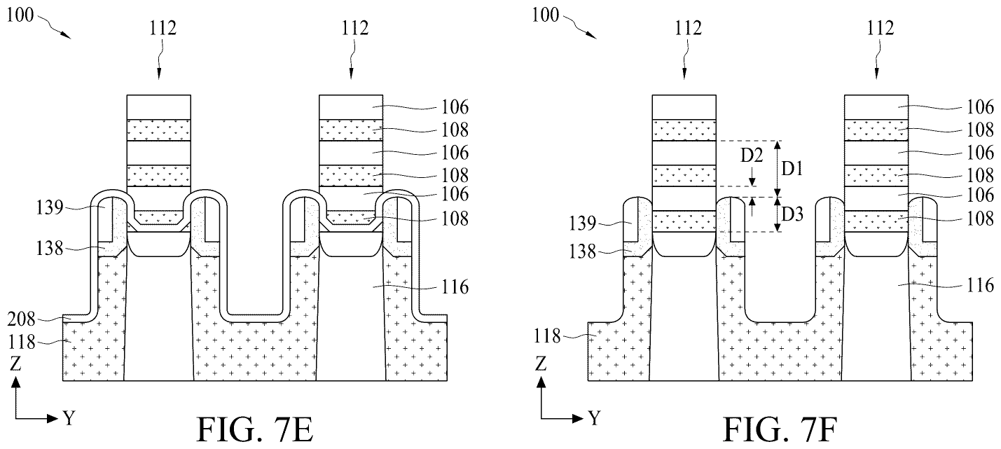

FIGS. 7A, 7B, 7C, 7D, 7E, and 7F are cross-sectional side views of various stages of manufacturing the semiconductor device structure 100 taken along line A-A of FIG. 5, in accordance with some embodiments. FIGS. 7A-7F illustrate the exposed portions of the fin structures 112. As shown in FIG. 7A, portions of the first and second spacers 138, 139 formed on horizontal surfaces of the semiconductor device structure 100 are removed. In some embodiments, a selective anisotropic etch process is performed to remove the portions of the first and second spacers 138, 139. The selective anisotropic etch process may be a plasma etch process that utilizes one or more carbon-containing etchants. In some embodiments, the one or more carbon-containing etchants include CH₄ and/or CHF₃. The plasma power of the plasma etch process may range from about 100 W to about 300 W, and a bias power may range from about 100 W to about 300 W. In some embodiments, dilute gas, such as He, Ar, and/or N₂, may be also used along with the one or more carbon-containing etchants. The flow rates of the gases may range from about 20 standard cubic centimeters per minute (sccm) to about 3000 sccm. The chamber pressure may range from about 1 mTorr to about 100 mTorr.

As shown in FIG. 7A, after the removal of the portions of the first and second spacers 138, 139, the topmost first semiconductor layer 106 is exposed. Next, as shown in FIG. 7B, a selective etch process is performed to recess the exposed portions of the fin structures 112. The selective etch process etches the semiconductor materials of the first and second semiconductor layers 106, 108 at a faster rate than the dielectric materials of the first and second spacers 138, 139, the insulating material 118, and the mask layer 136 (FIG. 5). In some embodiments, the selective etch process is a plasma process that utilizes one or more halogen-containing etchants. In some embodiments, the one or more halogen-containing etchants include HBr, Cl₂, or a combination thereon. The one or more halogen-containing etchants etch the semiconductor materials at a faster rate than the dielectric materials. In some embodiments, oxygen gas (O₂) is also used along with the one or more halogen-containing etchants to further improve etch selectivity. In some embodiments, dilute gas, such as He, Ar, and/or N₂, may be also used along with the one or more halogen-containing etchants. The flow rates of the gases may range from about 20 standard cubic centimeters per minute (sccm) to about 3000 sccm. The chamber pressure may range from about 1 mTorr to about 100 mTorr.

In some embodiments, after the removal of a portion of the fin structure 112, a byproduct layer 202 is formed on surfaces below the topmost first semiconductor layer 106, as shown in FIG. 7B. The byproduct layer 202 may be an oxide, such as SiO₂ or SiO. The byproduct layer 202 may be a continuous layer formed on the surfaces of the semiconductor device structure 100 below the topmost first semiconductor layer 106, as shown in FIG. 7B. For example, the byproduct layer 202 may be formed on the insulating material 118, the recessed fin structures 112, and the first and second spacers 138, 139 located on opposite sides of the recessed fin structures 112. The byproduct layer 202 may be also formed on the side surfaces of the first and second spacers 138, 139 located on opposite sides of each fin structure 112, as shown in FIG. 7B. In some embodiments, after the byproduct layer 202 reaches a predetermined thickness, such as from about 1 nm to about 5 nm, for example from about 2 nm to about 3 nm, additional processes are performed to passivate the first and second spacers 138, 139 located on opposite sides of the fin structure 112. The byproduct layer 202 (or other byproduct layers 204, 206) is utilized to slow the reduction of height of the first and second spacers 138, 139. Thus, if the thickness of the byproduct layer 202 (or other byproduct layers 204, 206) is less than about 1 nm, the byproduct layer 202 cannot effectively slow the reduction of height of the first and second spacers 138, 139. On the other hand, if the thickness of the byproduct layer 202 (or other byproduct layers 204, 206) is greater than about 5 nm, the process to remove the byproduct layer 202 may be too difficult.

In some embodiments, the additional processes include a passivation process and a treatment process. For example, after the byproduct layer 202 reaches the predetermined thickness, the selective etch process to recess the exposed portion of the fin structures 112 is stopped. In other words, the selective etch process is controlled so that the thickness of the byproduct layer 202 is within the predetermined range. Then, a passivation process is performed to improve the etch selectivity of the byproduct layer 202. The passivation process may be a plasma treatment process utilizing a nitrogen-containing or an oxygen-containing gas. In other words, the byproduct layer 202 is exposed to a nitrogen-containing plasma or an oxygen-containing plasma during the passivation process. In some embodiments, the nitrogen-containing gas is N₂ gas, and the oxygen-containing gas is O₂ gas. In some embodiments, the nitrogen-containing gas is used in the passivation process, and the byproduct layer 202 is converted from an oxide layer to a nitride layer. In some embodiments, the oxygen-containing gas is used in the passivation process, and the quality of the oxide layer of the byproduct layer 202 is improved. The byproduct layer 202 after the passivation process has an improved etch selectivity in the subsequent etch processes. The plasma power of the plasma treatment process may be greater than the plasma power of the selective etch process to recess the fin structures 112. In some embodiments, the plasma power of the plasma treatment process ranges from about 200 W to about 500 W. The bias power of the plasma treatment process may be less than the bias power of the selective etch process to recess the fin structures 112. In some embodiments, the bias power of the plasma treatment process ranges from about 10 W to about 50 W. In some embodiments, the flow rates of the gases may range from about 20 standard cubic centimeters per minute (sccm) to about 3000 sccm. The chamber pressure may range from about 1 mTorr to about 100 mTorr.

After treating the byproduct layer 202 with the nitrogen-containing plasma or the oxygen-containing plasma, a softening process is performed on the byproduct layer 202. In some embodiments, the softening process is a plasma treatment process utilizing a hydrogen-containing gas. In other words, the byproduct layer 202 is exposed to a hydrogen-containing plasma during the softening process. In some embodiments, the hydrogen-containing gas is H₂ gas. The softening process bombards the byproduct layer 202 to soften the byproduct layer 202. As a result, the byproduct layer 202 is easier to remove. The plasma power of the softening process may be less than the plasma power of the passivation process. In some embodiments, the plasma power of the softening process ranges from about 50 W to about 100 W. The bias power of the softening process may be greater than the bias power of the passivation process. In some embodiments, the bias power of the softening process ranges from about 200 W to about 400 W. In some embodiments, the flow rates of the gases may range from about 20 standard cubic centimeters per minute (sccm) to about 3000 sccm. The chamber pressure may range from about 50 mTorr to about 100 mTorr.

The first and second semiconductor layers 106, 108 shown over the byproduct layer 202 in FIG. 7B are located at a different location along the X direction compared to the first and semiconductor layers 106, 108 shown below the byproduct layer 202 in FIG. 7B. In other words, the first and second semiconductor layers 106, 108 shown over the byproduct layer 202 in FIG. 7B are the remaining first and second semiconductor layers 106, 108 located under the first and second spacers 138, 139 formed along the side surface of the sacrificial gate electrode layer 134 (FIG. 6A). The same method of illustration applies to subsequent figures, such as FIGS. 7C to 7F, 8B, 9B, 10B, 11B, 16B, 17B, and 18B.

Next, as shown in FIG. 7C, the exposed fin structures 112 are further recessed, and another byproduct layer 204 is formed. After the softening process, a selective anisotropic etch process is performed to remove portions of the byproduct layer 202 formed on horizontal surfaces of the semiconductor device structure 100. For example, the portions of the byproduct layer 202 formed on the fin structures 112 and the insulating material 118 are removed. In some embodiments, the portions of the byproduct layer 202 formed on the first and second spacers 138, 139 located on opposite sides of each fin structure 112 are recessed but not completely removed, as a result of a small dimension of the first and second spacers 138, 139 along the Y direction. The selective anisotropic etch process may be a plasma etch process utilizing a carbon-containing etchant, such as CH₄ and/or CHF₃. The duration of the plasma etch process may be short due to the small thickness of the byproduct layer 202 and the softening process. In some embodiments, the duration of the plasma etch process is less than about 5 seconds, such as from about 1 second to about 3 seconds.

After the selective anisotropic etch process, the recessed fin structures 112 are exposed, and the byproduct layer 202 remains on the first and second spacers 138, 139 located on opposite sides of each recessed fin structure 112. Next, the recessed fin structures 112 are further recessed. The further recess of the recessed fin structures 112 may be performed by the selective etch process described above, with the exception of higher bias power, such as from about 200 W to about 500 W. The remaining byproduct layer 202 formed on the first and second spacers 138, 139 may be removed by the selective etch process, and the height of the first and second spacers 138, 139 along the Z direction may be reduced slightly by the selective etch process. In other words, without the byproduct layer 202 that has been treated with the nitrogen-containing plasma or the oxygen-containing plasma, the height of the first and second spacers 138, 139 may be reduced significantly by the selective etch process.

Similarly, another byproduct layer 204 is formed during the selective etch process. The byproduct layer 204 may include the same material as the byproduct layer 202. The byproduct layer 204 may be formed on the insulating material 118, the recessed fin structures 112, and the first and second spacers 138, 139 located on opposite sides of each recessed fin structures 112. The byproduct layer 204 may be also formed adjacent the side surfaces of the first and second spacers 138, 139 located on opposite sides of each recessed fin structure 112. In some embodiments, the byproduct layer 202 may remain on the side surfaces of the first and second spacers 138, 139 located on opposite sides of each recessed fin structure 112, and the byproduct layer 202 is disposed between the side surfaces of the first and second spacers 138, 139 and the byproduct layer 204.

Similar to the byproduct layer 202, the byproduct layer 204 has a thickness ranging from about 1 nm to about 5 nm, such as from about 2 nm to about 3 nm. The selective etch process to further recess the fin structures 112 is stopped by the thickness of the byproduct layer 204 reaches the predetermined range. Next, the passivation process is performed on the byproduct layer 204. In some embodiments, the passivation process is the same passivation process performed on the byproduct layer 202, with the exception of higher bias power. The bias power of the passivation process performed on the byproduct layer 204 may range from about 20 W to about 80 W. The higher bias power is used because the byproduct layer 204 is located at a level along the Z direction below the byproduct layer 202. After the passivation process, the byproduct layer 204 is converted to a nitride layer or a high-quality oxide layer. Next, the softening process is performed on the byproduct layer 204 to soften the byproduct layer 204. In some embodiments, the softening process is the same softening process performed on the byproduct layer 202, with the exception of higher bias power. The bias power of the softening process performed on the byproduct layer 204 may range from about 300 W to about 500 W. The higher bias power is used because the byproduct layer 204 is located at a level along the Z direction below the byproduct layer 202.

In some embodiments, the etch processes to remove portions of the byproduct layer 202 and to further recess the fin structures 112, the passivation process to improve the quality of the byproduct layer 204, and the softening process to soften the byproduct layer 204 are considered a cycle of a cyclic process. The cycle is repeated until the fin structures 112 are recessed to a predetermined level. As the fin structures 112 get shorter along the Z direction, the bias powers of the processes of the subsequent cycle are greater than the bias powers of the processes of the previous cycle. Furthermore, as described above, the passivation process is to increase the etch selectivity of the byproduct layer formed during the recess of the fin structures 112 in the etch process to further recess the fin structures 112 of the subsequent cycle, and the softening process is to make the byproduct layer easier to remove during the etch process of the subsequent cycle to remove the horizontal portions of the byproduct layer. The passivated and softened byproduct layer of each cycle slows the reduction of height of the first and second spacers 138, 139 located on opposite sides of the recessed fin structures 112.

As shown in FIG. 7D, another cycle of processes are performed on the semiconductor device structure 100. The fin structures 112 are further recessed, and another byproduct layer 206 are formed. The etch processes to remove horizontal portions of the byproduct layer 204 and to further recess the fin structures 112 include higher bias power than that in the previous cycle, such as from about 300 W to about 600 W. The byproduct layer 206 is passivated by the passivation process having a higher bias power than that in the previous cycle, such as from about 50 W to about 100 W, and the byproduct layer 206 is softened by the softening process having a higher bias power than that in the previous cycle, such as from about 500 W to about 1000 W.

As shown in FIG. 7E, an etch process is performed to remove horizontal portions of the byproduct layer 206, the fin structures 112 are further recessed, and another byproduct layer 208 are formed. The etch processes to remove horizontal portions of the byproduct layer 206 and to further recess the fin structures 112 may be the same etch processes in the previous cycle. In some embodiments, the passivation process and the softening process are not performed on the byproduct layer 208. Instead, a wet clean process is performed to remove the byproduct layer 208, as shown in FIG. 7F. The wet clean process may also remove the byproduct layers 202, 204, 206 formed on the side surfaces of the first and second spacers 138, 139. The wet clean process may be a selective process that does not substantially affect the fin structures 112 and the first and second spacers 138, 139. In some embodiments, the wet clean process removes all of the byproduct layers 202, 204, 206, 208 from the semiconductor device structure 100. In some embodiments, the wet clean process may use any suitable solution, such as SC1 solution (a mixture of ammonia hydroxide, hydrogen peroxide, and water), SC2 solution (a mixture of hydrochloric acid, hydrogen peroxide, and water), hydrogen peroxide, deionized water, deionized ozone, or diluted hydrofluoric acid.

In some embodiments, the insulating material 118 is recessed by the etch processes of the cyclic process, as shown in FIG. 7F.

In some embodiments, as shown in FIG. 7F, three first semiconductor layers 106 and three second semiconductor layers 108 are included in the fin structure 112. With more first and second semiconductor layers 106, 108 in the fin structure 112, more cycles of processes may be performed to ensure the recess of the fin structure 112 does not cause the height of the first and second spacers 138, 139 to be small. If the height of the first and second spacers 138, 139 is too small, subsequently formed source/drain regions may merge, leading to current leak path.

The first and second semiconductor layers 106, 108 shown in FIG. 7F are located at a different location along the X direction compared to the first and second spacers 138, 139, as described above. In some embodiments, a distance D1 between the level of the top of the first and second spacers 138, 139 and the level of the bottom surface of the top second semiconductor layer 108 ranges from about 17 nm to about 18 nm, a distance D2 between the level of the top of the first and second spacers 138, 139 and the level of the bottom surface of the middle second semiconductor layer 108 ranges from about 2 nm to about 3 nm, and a distance D3 between the level of the top of the first and second spacers 138, 139 and the level of the bottom surface of the bottom second semiconductor layer 108 ranges from about 12 nm to about 13 nm. The level of the top of the first and second spacers 138, 139 is higher than the level of the bottom surface of the bottom second semiconductor layer 108, as shown in FIG. 7F.

Even though the semiconductor device structure 100 includes the first and second spacers 138, 139, as shown in FIGS. 7A to 7F, in some embodiments, the semiconductor device structure 100 includes a single spacer, such as the spacer 138, and the second spacer 139 is not present. The processes described in FIGS. 7A to 7F may be performed on the semiconductor device structure 100 with the single spacer 138, and the height of the single spacer 138 may be high enough to prevent the merging of subsequently formed source/drain regions as a result of the processes described in FIGS. 7A to 7F.

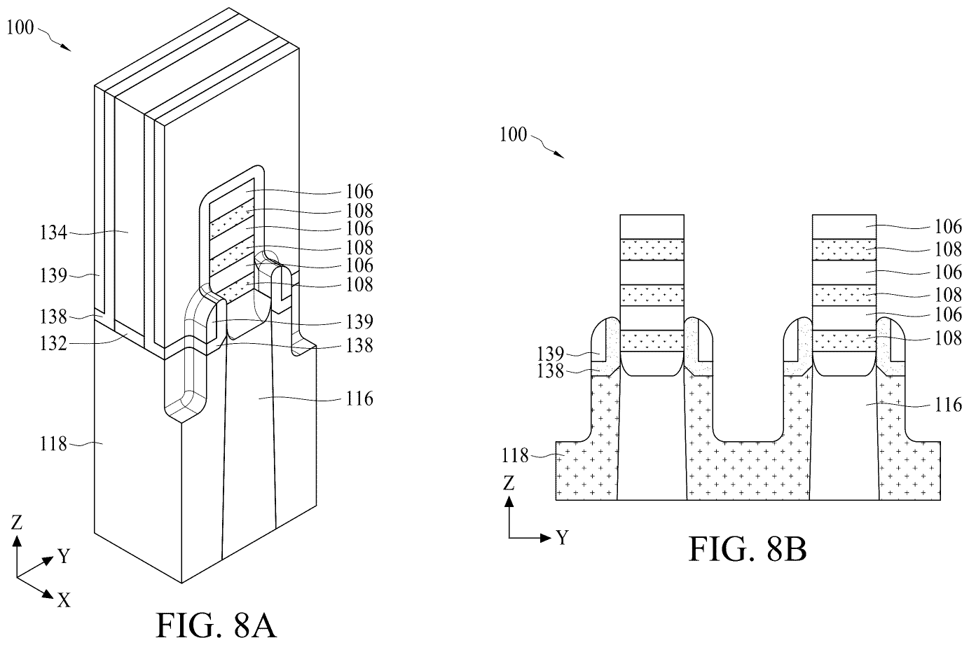

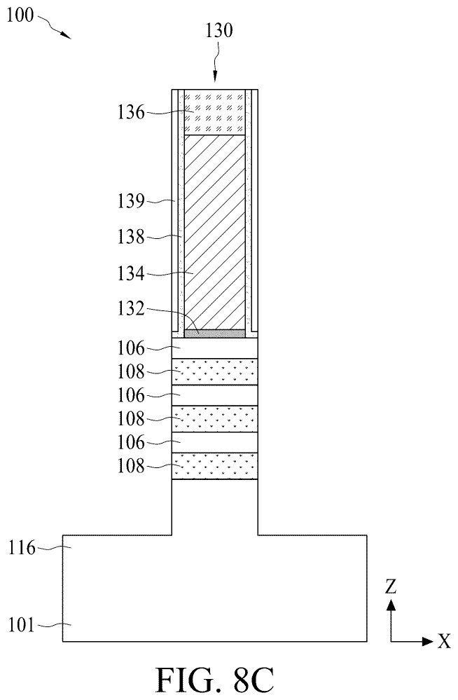

FIGS. 8A, 9A, 10A, and 11A are perspective views of various stages of manufacturing the semiconductor device structure 100, in accordance with some embodiments. FIGS. 8B, 9B, 10B, and 11B are cross-sectional side views of various stages of manufacturing the semiconductor device structure 100 taken along line A-A of FIG. 5, in accordance with some embodiments. FIGS. 8C, 9C, 10C, and 11C are cross-sectional side views of various stages of manufacturing the semiconductor device structure 100 taken along line B-B of FIG. 5, in accordance with some embodiments. FIGS. 8A, 8B, and 8C illustrate the semiconductor device structure 100 at the same manufacturing stage as the semiconductor device structure 100 shown in FIG. 7F.

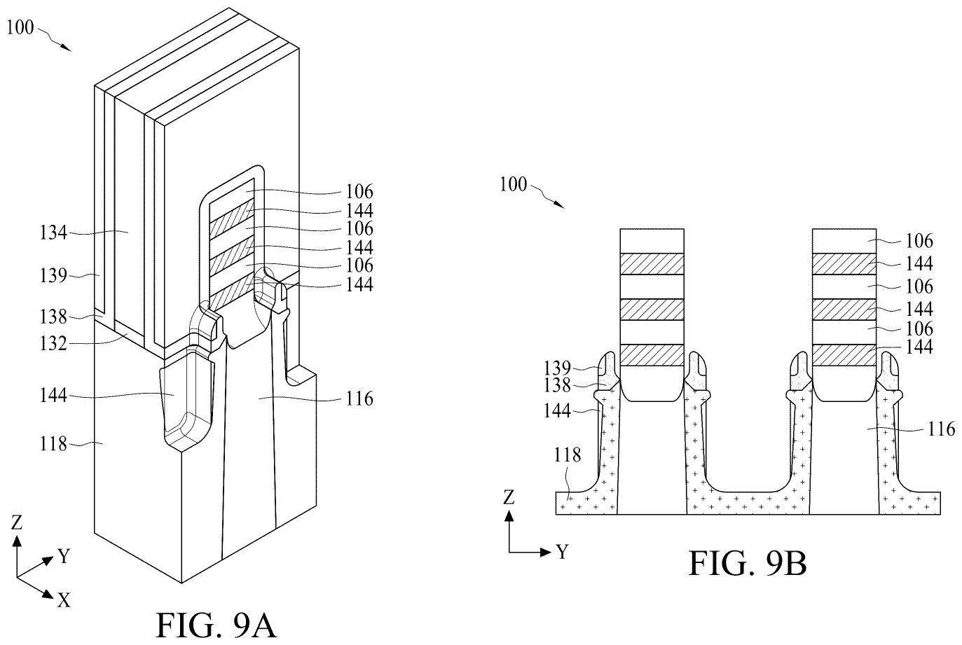

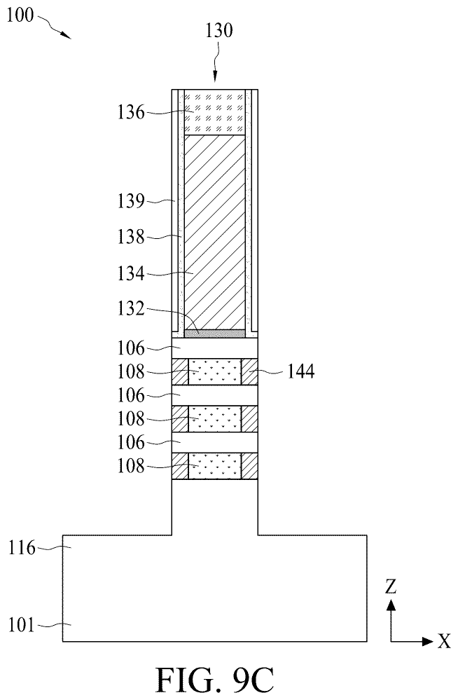

As shown in FIGS. 9A, 9B, and 9C, edge portions of each second semiconductor layer 108 of the stack of semiconductor layers 104 are removed horizontally along the X direction, and dielectric spacers 144 are formed in the space created by the removal of edge portions of the second semiconductor layers 108. The removal of the edge portions of the second semiconductor layers 108 forms cavities. In some embodiments, the portions of the second semiconductor layers 108 are removed by a selective wet etch process. In cases where the second semiconductor layers 108 are made of SiGe and the first semiconductor layers 106 are made of silicon, the second semiconductor layer 108 can be selectively etched using a wet etchant such as, but not limited to, ammonium hydroxide (NH₄OH), tetramethylammonium hydroxide (TMAH), ethylenediamine pyrocatechol (EDP), or potassium hydroxide (KOH) solutions.

After removing edge portions of each second semiconductor layers 108, a dielectric layer is deposited in the cavities to form the dielectric spacers 144. The dielectric spacers 144 may be made of a low-K dielectric material, such as SiON, SiCN, SiOC, SiOCN, SiO, or SiN. The dielectric spacers 144 may be formed by first forming a conformal dielectric layer using a conformal deposition process, such as ALD, followed by an anisotropic etching to remove portions of the conformal dielectric layer other than the dielectric spacers 144. The dielectric spacers 144 are protected by the first semiconductor layers 106 during the anisotropic etching process. The remaining second semiconductor layers 108 are capped between the dielectric spacers 144 along the X direction. In some embodiments, the dielectric spacer 144 is also formed on the side surfaces of the insulating material 118. In some embodiments, the height of the first and second spacers 138, 139 may be reduced slightly during the formation of the dielectric spacers 144, as shown in FIGS. 9A and 9B.

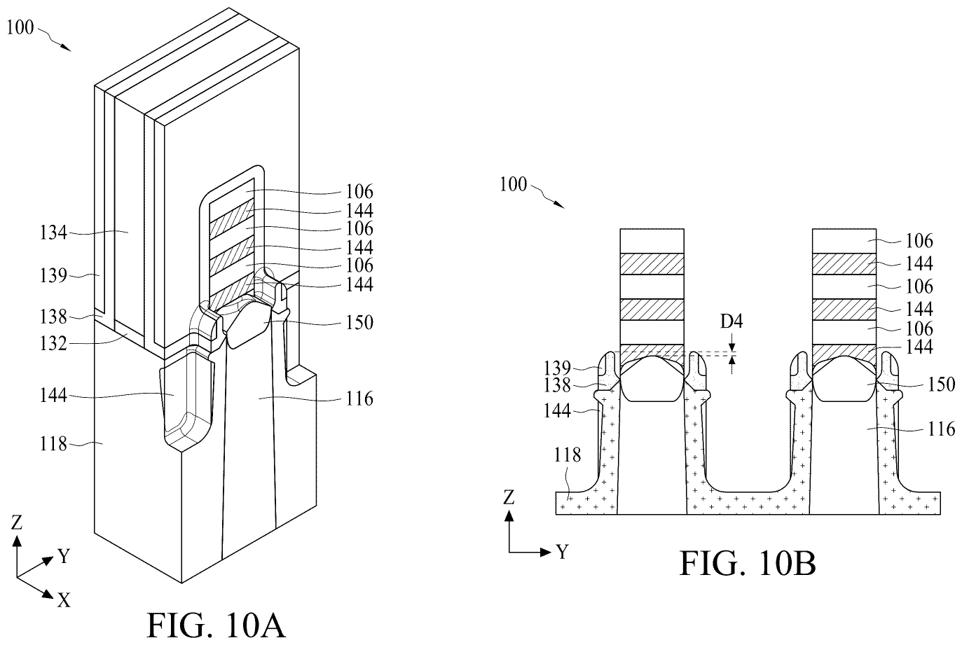

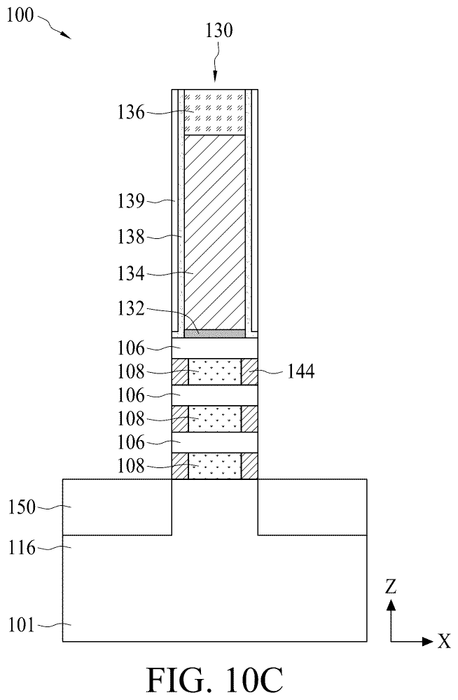

As shown in FIGS. 10A, 10B, and 10C, a first semiconductor material 150 is formed on the exposed substrate portion 116. In some embodiments, the first semiconductor material 150 includes undoped silicon or undoped SiGe. The first semiconductor material 150 may be first formed on semiconductor surfaces, such as on the exposed substrate portions 116 and on the first semiconductor layers 106, by epitaxy. A subsequent etch process is performed to remove the portions of the first semiconductor material 150 formed on the first semiconductor layers 106. In some embodiments, as shown in FIG. 10B, a distance D4 between the top of the first and second spacers 138, 139 and the top of the first semiconductor material 150 is greater than or equal to 5 nm, such as from about 5 nm to about 6 nm.

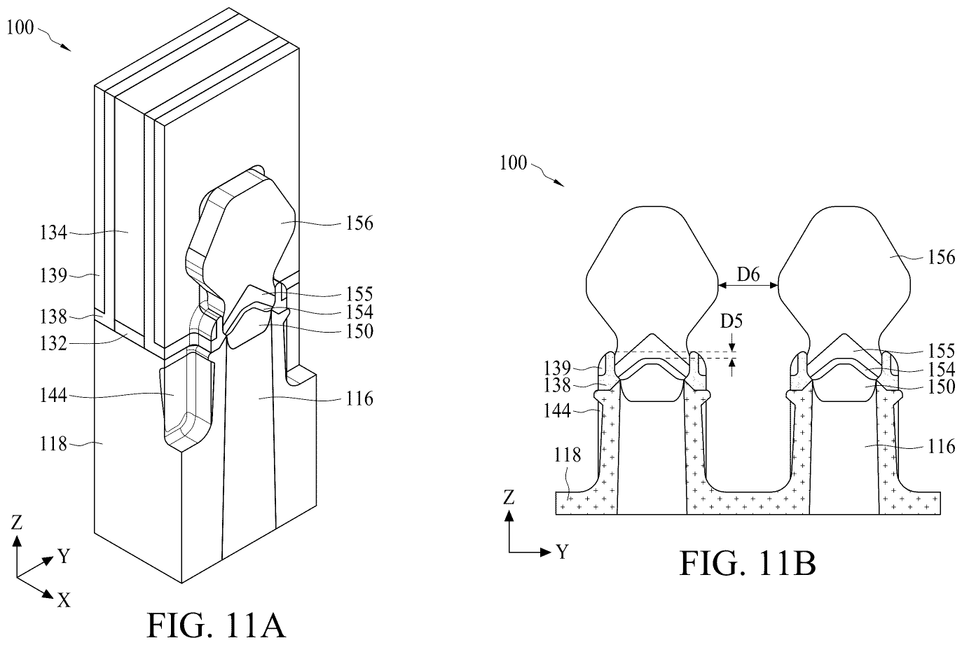

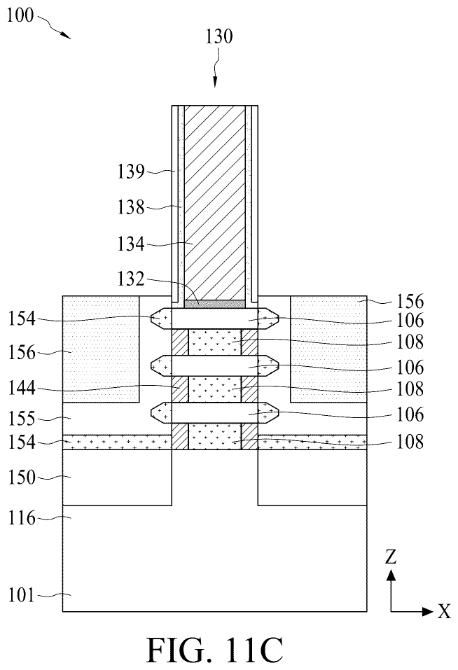

As shown in FIGS. 11A, 11B, and 11C, a second semiconductor material 154 is formed from the first semiconductor layers 106 and the first semiconductor material 150. The second semiconductor material 154 may be made of one or more layers of Si, SiP, SiC, SiAs, SiSb, and SiCP for n-channel FETs or Si, SiGe, Ge, SiGeB for p-channel FETs. For p-channel FETs, p-type dopants, such as boron (B), may be included in the second semiconductor material 154. For n-channel FETs, n-type dopants, such as phosphorus (P) or arsenic (As), may be included in the second semiconductor material 154. In some embodiments, the dopant concentration of the second semiconductor material 154 may range from about 1×10¹⁹ cm⁻³ to about 2×10²¹ cm⁻³. The second semiconductor material 154 may be formed by an epitaxial growth method using CVD, ALD or MBE. As shown in FIGS. 11A, 11B, and 11C, in some embodiments, the second semiconductor material 154 is selectively formed on semiconductor materials, such as the first semiconductor layers 106 and the first semiconductor material 150, and is not formed on dielectric materials, such as the dielectric spacers 144. In some embodiments, the second semiconductor material 154 includes facets, which may correspond to crystalline planes of the material used for the first semiconductor layers 106 and the first semiconductor material 150. In some embodiments, the second semiconductor material 154 includes discrete portions extending from the first semiconductor layers 106 along the X direction.

Next, as shown in FIGS. 11A, 11B, and 11C, a third semiconductor material 155 is formed from the second semiconductor material 154, and a fourth semiconductor material 156 is formed from the third semiconductor material 155. The third semiconductor material and fourth semiconductor materials 155, 156 may be formed by an epitaxial growth method using CVD, ALD or MBE. The third semiconductor material 155 may be made of the same material as the second semiconductor material 154 but with higher dopant concentration, and the fourth semiconductor material 156 may be made of the same material as the third semiconductor material 155 but with higher dopant concentration.

In some embodiments, a cap layer (not shown) may be formed on the fourth semiconductor material 156. The cap layer may include a semiconductor material. In some embodiments, the cap layer includes the same material as the fourth semiconductor material. The cap layer may be epitaxially grown from the fourth semiconductor material 156. The first semiconductor material 150, the second semiconductor material 154, the third semiconductor material 155, and the fourth semiconductor material 156 together may be the source/drain (S/D) region. In this disclosure, a source region and a drain region are interchangeably used, and the structures thereof are substantially the same. Furthermore, source/drain region(s) may refer to a source or a drain, individually or collectively dependent upon the context. In some embodiments, p-type S/D regions and n-type S/D regions may be formed separately using one or more mask layers.

In some embodiments, as shown in FIG. 11B, a distance D5 between the top of the first and second spacers 138, 139 and the top of the second semiconductor material 154 is greater than about 3 nm, such as from about 3 nm to about 6 nm. In some embodiments, as a result of the taller first and second spacers 138, 139, a distance D6 between adjacent fourth semiconductor material 156 ranges from about 10 nm to about 12 nm.

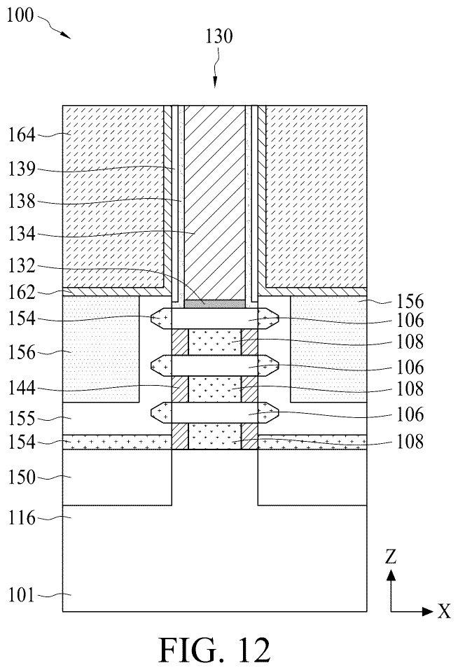

FIGS. 12, 13, and 14 are cross-sectional side views of various stages of manufacturing the semiconductor device structure 100 taken along line B-B of FIG. 5, in accordance with some embodiments. As shown in FIG. 12, a contact etch stop layer (CESL) 162 is conformally formed on the exposed surfaces of the semiconductor device structure 100. The CESL 162 covers the second spacer 139, the insulating material 118, and the fourth semiconductor material 156 (or the cap layer if present). The CESL 162 may include an oxygen-containing material or a nitrogen-containing material, such as silicon nitride, silicon carbon nitride, silicon oxynitride, carbon nitride, silicon oxide, silicon carbon oxide, or the like, or a combination thereof, and may be formed by CVD, PECVD, ALD, or any suitable deposition technique. In some embodiments, the CESL 162 is a single layer, as shown in FIG. 12. In some embodiments, the CESL 162 includes two or more layers. Next, an interlayer dielectric (ILD) layer 164 is formed on the CESL 162. The materials for the ILD layer 164 may include compounds including Si, O, C, and/or H, such as silicon oxide, SiCOH, or SiOC. Organic materials, such as polymers, may also be used for the ILD layer 164. The ILD layer 164 may be deposited by a PECVD process or other suitable deposition technique. In some embodiments, after formation of the ILD layer 164, the semiconductor device structure 100 may be subject to a thermal process to anneal the ILD layer 164.

After the ILD layer 164 is formed, a planarization operation, such as CMP, is performed on the semiconductor device structure 100 until the sacrificial gate electrode layer 134 is exposed, as shown in FIG. 12.

Next, as shown in FIG. 13, the sacrificial gate structure 130 and the second semiconductor layers 108 are removed. The removal of the sacrificial gate structure 130 and the semiconductor layers 108 forms an opening between the first spacers 138 and between the first semiconductor layers 106. The ILD layer 164 protects the second semiconductor material 156 during the removal processes. The sacrificial gate structure 130 can be removed using plasma dry etching and/or wet etching. The sacrificial gate electrode layer 134 may be first removed by any suitable process, such as dry etch, wet etch, or a combination thereof, followed by the removal of the sacrificial gate dielectric layer 132, which may also be performed by any suitable process, such as dry etch, wet etch, or a combination thereof. In some embodiments, a wet etchant such as a tetramethylammonium hydroxide (TMAH) solution can be used to selectively remove the sacrificial gate electrode layer 134 but not the first spacers 138, the ILD layer 164, and the CESL 162.

The second semiconductor layers 108 may be removed using a selective wet etching process. In cases where the second semiconductor layers 108 are made of SiGe and the first semiconductor layers 106 are made of Si, the chemistry used in the selective wet etching process removes the SiGe while not substantially affecting Si, the dielectric materials of the first spacers 138, and the dielectric spacers 144. In one embodiment, the second semiconductor layers 108 can be removed using a wet etchant such as, but not limited to, hydrofluoric (HF), nitric acid (HNO₃), hydrochloric acid (HCl), or phosphoric acid (H₃PO₄).

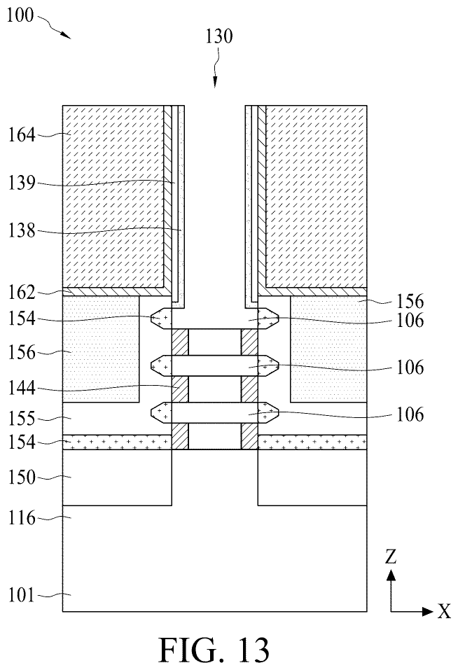

As shown in FIG. 14, after the formation of the nanostructure channels (i.e., the exposed portions of the first semiconductor layers 106), a gate dielectric layer 170 is formed to surround the exposed portions of the first semiconductor layers 106, and a gate electrode layer 172 is formed on the gate dielectric layer 170. The gate dielectric layer 170 and the gate electrode layer 172 may be collectively referred to as a gate structure 174. In some embodiments, an interfacial layer (IL) (not shown) is formed between the gate dielectric layer 170 and the exposed surfaces of the first semiconductor layers 106. In some embodiments, the gate dielectric layer 170 includes one or more layers of a dielectric material, such as silicon oxide, silicon nitride, or high-K dielectric material, other suitable dielectric material, and/or combinations thereof. Examples of high-K dielectric material include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-K dielectric materials, and/or combinations thereof. The gate dielectric layer 170 may be formed by CVD, ALD or any suitable deposition technique. The gate electrode layer 172 may include one or more layers of conductive material, such as polysilicon, aluminum, copper, titanium, tantalum, tungsten, cobalt, molybdenum, tantalum nitride, nickel silicide, cobalt silicide, TIN, WN, TiAl, TiAIN, TaCN, TaC, TaSiN, metal alloys, other suitable materials, and/or any combinations thereof. The gate electrode layer 172 may be formed by CVD, ALD, electro-plating, or other suitable deposition technique. The gate electrode layer 172 may be also deposited over the ILD layer 164. The gate dielectric layer 170 and the gate electrode layer 172 formed over the ILD layer 164 are then removed by using, for example, CMP, until the top surfaces of the ILD layer 164 are exposed.

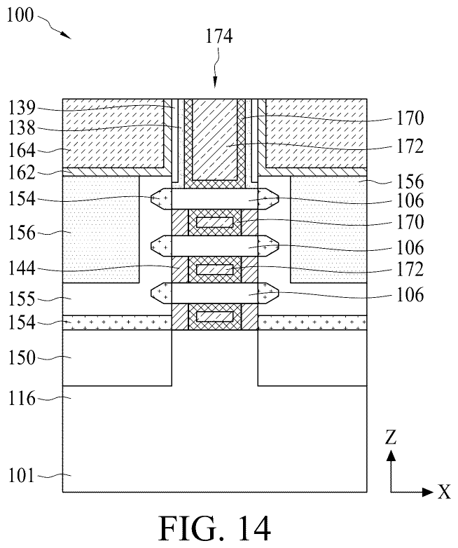

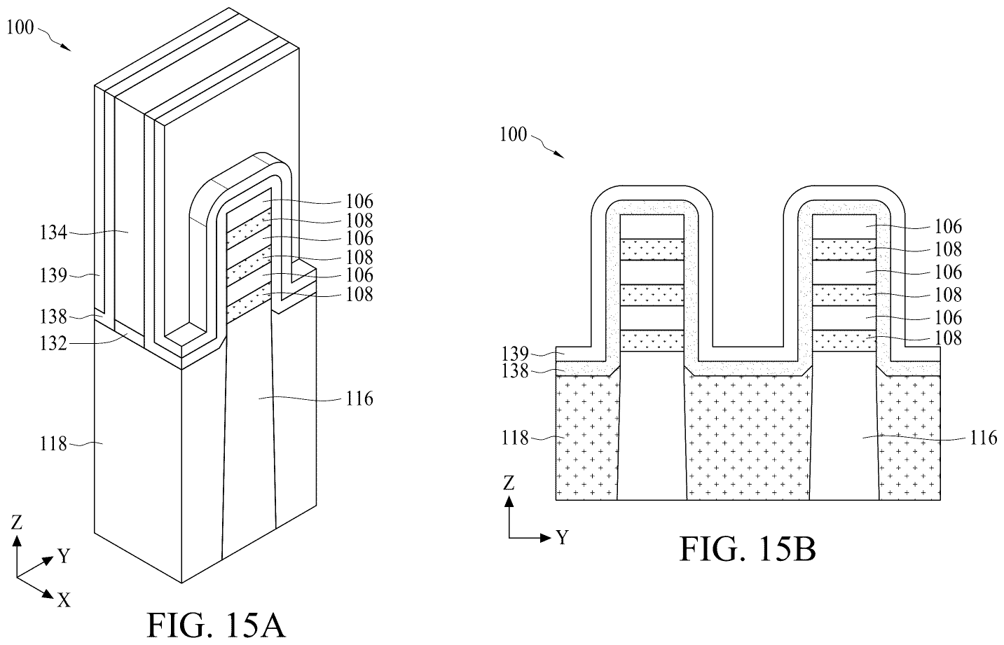

FIGS. 15A, 16A, 17A, 18A, and 19A are perspective views of various stages of manufacturing the semiconductor device structure 100, in accordance with alternative embodiments. FIGS. 15B, 16B, 17B, 18B, and 19B are cross-sectional side views of various stages of manufacturing the semiconductor device structure 100 taken along line A-A of FIG. 5, in accordance with alternative embodiments. As shown in FIGS. 15A and 15B, the first and second spacers 138, 139 are formed on the semiconductor device structure 100. In some embodiments, only one spacer is formed. The semiconductor device structure 100 shown in FIGS. 15A and 15B is at the same manufacturing stage as the semiconductor device structure 100 shown in FIGS. 6A and 6B.

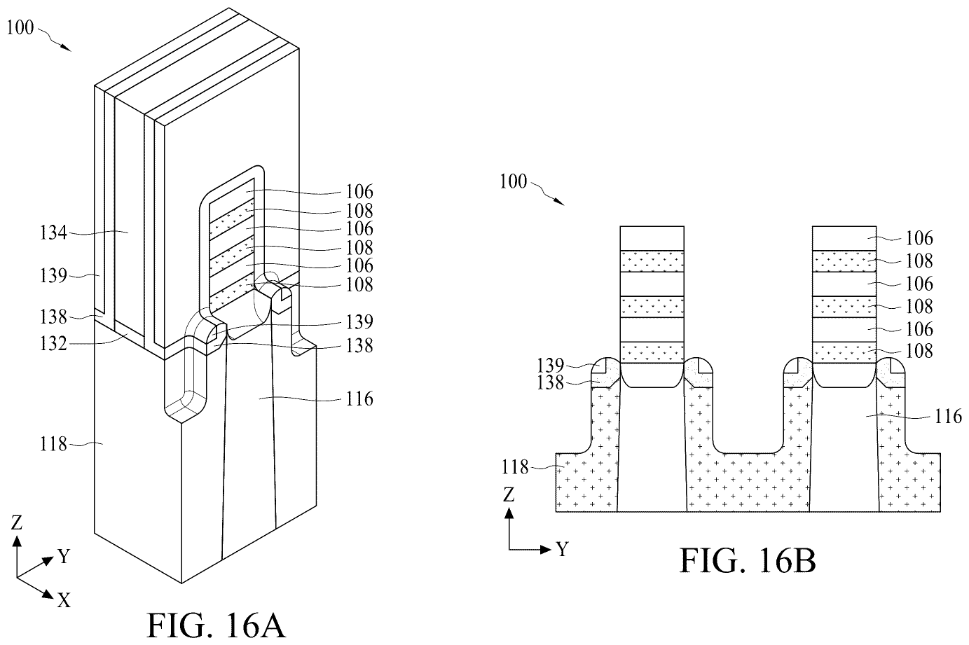

Next, as shown in FIGS. 16A and 16B, the portions of the fin structures 112 not covered by the sacrificial gate structures 130 and the first and second spacers 138, 139 formed on sidewalls of the sacrificial gate structures 130 are recessed. The portions of the first and second spacers 138, 139 located on opposite sides of the recessed fin structures 112 are also recessed. Instead of a cyclic process described in FIGS. 7A to 7F, the fin structures 112 may be recessed by a single etch process. As a result, the height of the first and second spacers 138, 139 is substantially reduced. The height of the first and second spacers 138, 139 is substantially shorter than the height of the first and second spacers 138, 139 shown in FIG. 8B.

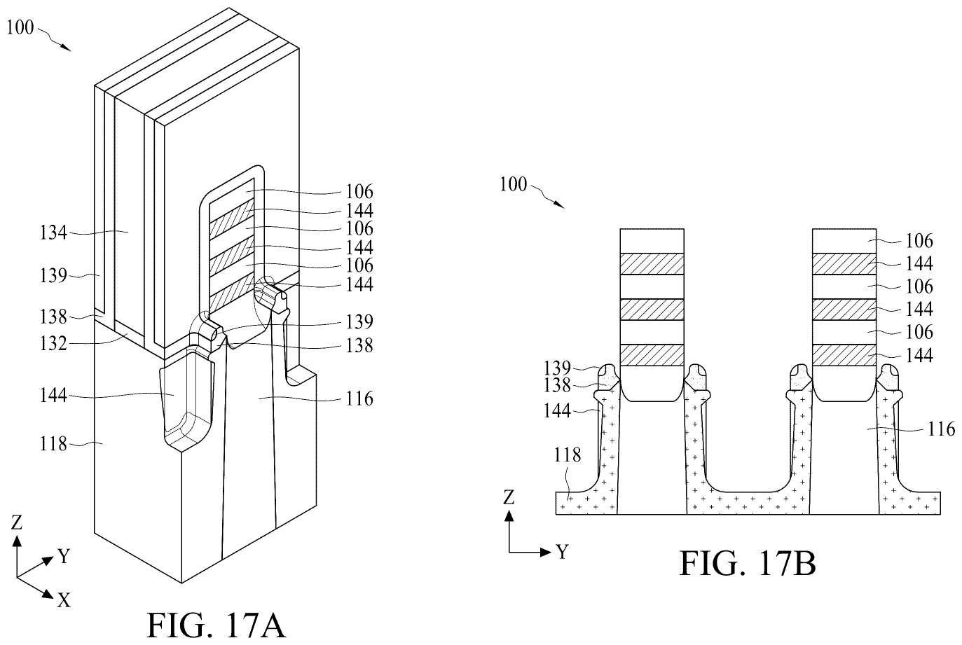

As shown in FIGS. 17A and 17B, the second semiconductor layers 108 are laterally recessed, and the dielectric spacers 144 are formed. The height of the first and second spacers 138, 139 is further reduced. In some embodiments, the second spacer 139 is removed from the first spacer 138. In some embodiments, a small amount of the second spacer 139 remains on the first spacer 138.

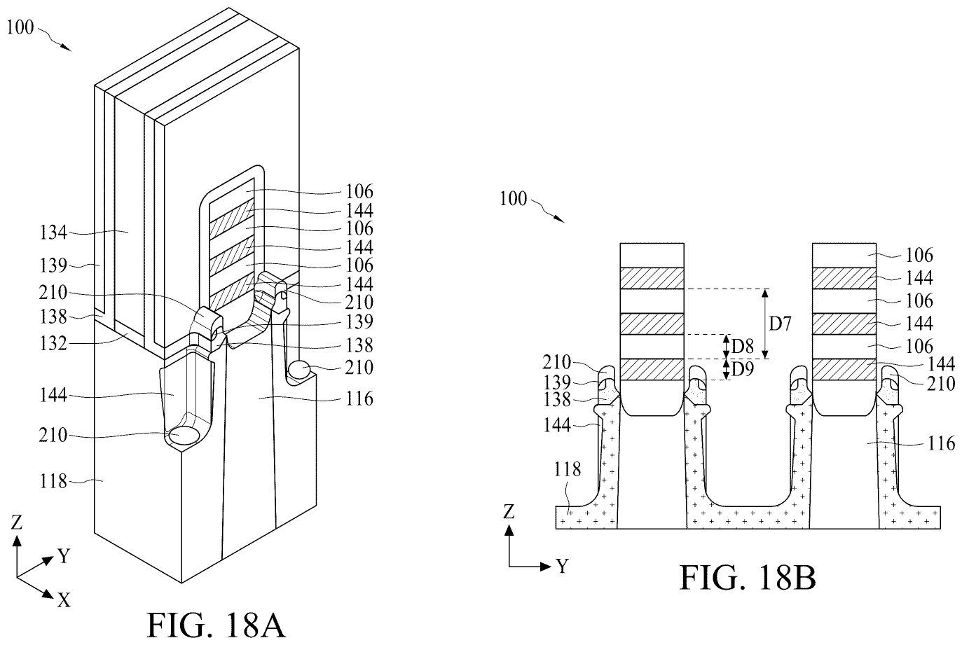

Next, as shown in FIGS. 18A and 18B, a dielectric layer 210 is selectively formed on the first and second spacers 138, 139 located on opposite sides of the recessed fin structures 112. In some embodiments, the dielectric layer 210 is an oxide, such as a silicon-containing oxide. The dielectric layer 210 is selectively formed on the top of the first and second spacers 138, 139 by any suitable method. In some embodiments, the dielectric layer 210 is made of SiONC having 30 to 45 atomic percent of Si, 30 to 45 atomic percent of 0, 20 to 30 atomic percent of N, and two to 10 atomic percent of C. In some embodiments, the dielectric layer 210 is formed by a cyclic process. Each cycle of the cyclic process includes a deposition process, a treatment process, and a thermal process. The deposition process may be a plasma deposition process, such as a plasma enhanced chemical vapor deposition (PECVD) process. For example, a silicon-containing precursor and one or more reactive gases are flowed into a processing chamber, in which the semiconductor device structure 100 is disposed therein, and a plasma is formed in the processing chamber. The silicon-containing precursor may be any suitable silicon-containing material, such as

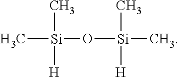

In some embodiments, the one or more reactive gases includes H₂, N₂, and O₂. The reactive species, such as hydrogen ions and radicals, nitrogen ions and radicals, and oxygen ions and radicals, formed in the plasma react with the silicon-containing precursor to form a layer on the semiconductor device structure 100. In some embodiments, the layer includes

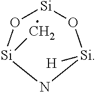

The layer may be a non-conformal layer based on the material it formed thereon and the location. The layer may have varying thicknesses and may be selectively deposited on dielectric surfaces and not on the semiconductor surfaces. For example, the portions of the layer formed on the horizontal dielectric surfaces have a first thickness, the portions of the layer formed on the vertical dielectric surfaces have a second thickness less than the first thickness, the portions of the layer formed on the horizontal semiconductor surfaces have a third thickness less than the second thickness, and the portions of the layer formed on the vertical semiconductor surfaces have a fourth thickness less than the third thickness. Thus, in some embodiments, the portions of the layer formed on the top of the first and second spacers 138, 139, on the mask layer 136 (FIG. 5), and on the horizontal surface of the insulating material 118 have the greatest thickness, and the portions of the layer formed on the sidewalls of the second spacer 139 adjacent the sacrificial gate structure 130, on the dielectric spacers 144, on the first semiconductor layers 106, and on the substrate portions 116 have smaller thicknesses. In some embodiments, the PECVD process has a bias power ranging from about 700 W to about 800 W.

Next, a treatment process is performed on the layer to cross-link the molecules of the layer. In some embodiments, the treatment process is a plasma treatment process utilizing hydrogen species, such as hydrogen ions and hydrogen radicals. The resulting cross-linked layer may include

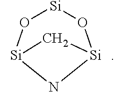

Next, a thermal process is performed to form the dielectric layer 210. The thermal process may be any suitable thermal process, such as an anneal process. In some embodiments, the thermal process includes heating the layer to a temperature ranging from about 500 degrees Celsius to about 650 degrees Celsius. The resulting dielectric layer 210 may include

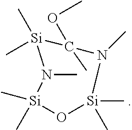

The cycle may be repeated until the dielectric layer 210 reaches a predetermined thickness, such as from about 10 nm to about 12 nm. As described above, the dielectric layer 210 is a non-conformal layer. The 10 nm to about 12 nm thickness is referring to the thickest portion of the dielectric layer 210, such as the portion disposed on the top of the first and second spacers 138, 139. In some embodiments, four to five cycles are performed to form the dielectric layer 210 having the predetermined thickness. Next, a trimming process is performed to remove portions of the dielectric layer 210 formed on the semiconductor surfaces and on the vertical dielectric surfaces. The trimming process may be a dry etch process, a wet etch process, or a combination thereon. Because the portions of the dielectric layer 210 formed on the top of the first and second spacers 138, 139, on the mask layer 136, and on the insulating material 118 have the greatest thickness, these portions of the dielectric layer 210 remain after the trimming process. Portions of the dielectric layer 210 formed at other locations are removed by the trimming process.

In some embodiments, a distance D7 between the level of the top of the dielectric layer 210 and the level of the bottom surface of the top second semiconductor layer 108 (now covered by the dielectric spacer 144) ranges from about 23 nm to about 25 nm, a distance D8 between the level of the top of the dielectric layer 210 and the level of the bottom surface of the middle second semiconductor layer 108 (now covered by the dielectric spacer 144) ranges from about 8 nm to about 10 nm, and a distance D9 between the level of the top of the dielectric layer 210 and the level of the bottom surface of the bottom second semiconductor layer 108 (now covered by the dielectric spacer 144) ranges from about 6 nm to about 8 nm. The level of the top of the dielectric layer 210 is higher than the level of the bottom surface of the bottom second semiconductor layer 108, as shown in FIG. 18B.

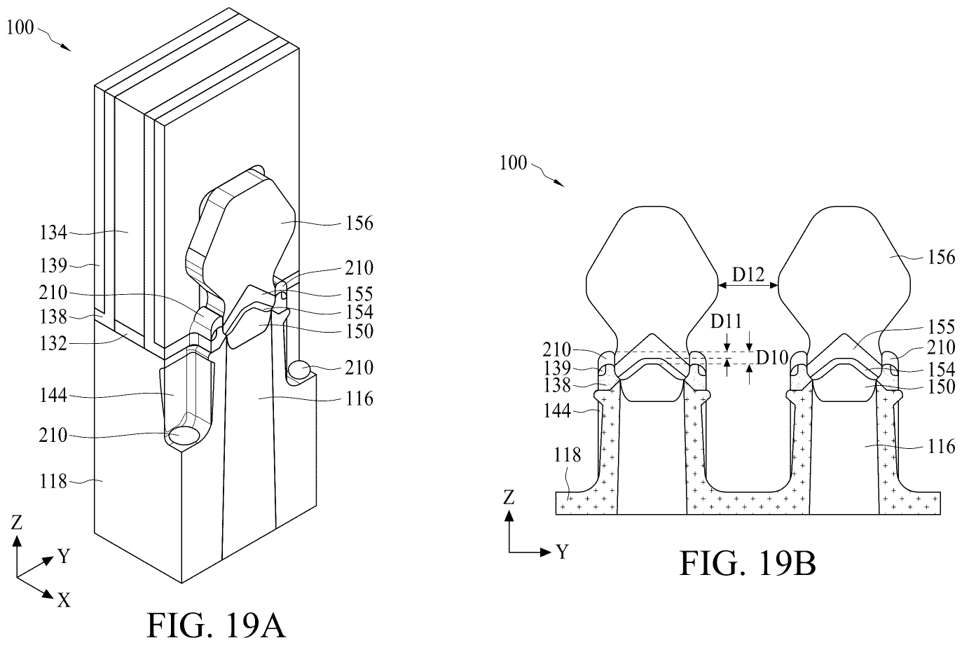

As shown in FIGS. 19A and 19B, the first, second, third, and fourth semiconductor materials 150, 154, 155, 156 are formed on the substrate portion 116. In some embodiments, a distance D10 between the top of the dielectric layer 210 and the top of the first semiconductor material 150 is greater than or equal to 7 nm, such as from about 7 nm to about 8 nm. A distance D11 between the top of the dielectric layer 210 and the top of the second semiconductor material 154 is greater than or equal to about 5 nm, such as from about 5 nm to about 6 nm. In some embodiments, as a result of having the dielectric layer 210 formed on the first and second spacers 138, 139, a distance D12 between adjacent fourth semiconductor material 156 ranges from about 12 nm to about 14 nm.

Subsequent processes, such as the processes described in FIGS. 12 to 14 are performed. In some embodiments, the CESL 162 and the ILD layer 164 are formed on the dielectric layer 210 adjacent the source/drain region and on the dielectric layer 210 on the insulating material 118. The planarization process performed to remove portions of the ILD layer 164 formed over the sacrificial gate structures 130 may also remove the portion of the dielectric layer 210 formed on the mask layer 136.

Embodiments of the present disclosure provide a semiconductor device structure and methods of forming the same. In some embodiments, the semiconductor device structure 100 includes one or more spacers 138, 139 having increased height to prevent adjacent S/D regions from merging. In some embodiments, a cyclic process is performed during the recess of the fin structures 112. The cyclic process includes passivating and softening a byproduct layer 202, 204, 206, and the passivated byproduct layer 202, 204, 206 slows the reduction of height of the one or more spacers 138, 139 during the recess of the fin structures 112. Some embodiments may achieve advantages. For example, with the increased height of the one or more spacers 138, 139, the merging of the S/D regions is prevented. As a result, current leakage path is prevented.

An embodiment is a method. The method includes forming a fin structure over a substrate and depositing one or more spacers on a portion of the fin structure. The one or more spacers are deposited on sidewalls of the fin structure. The method further includes removing a first portion of the one or more spacers to expose the fin structure and recessing the fin structure. A first byproduct layer is formed on a second portion of the one or more spacers. The method further includes passivating the first byproduct layer, softening the first byproduct layer, removing a portion of the first byproduct layer to expose the recessed fin structure, and further recessing the fin structure.

Another embodiment is a method. The method includes forming a fin structure over a substrate and depositing one or more spacers on a portion of the fin structure. The one or more spacers are deposited on sidewalls of the fin structure. The method further includes removing a first portion of the one or more spacers to expose the fin structure and recessing the fin structure to expose a substrate portion. A second portion of the one or more spacers located on a sidewall of the fin structure is recessed. The method further includes selectively depositing a dielectric layer on the recessed second portion of the one or more spacers and depositing a semiconductor material on the substrate portion.

A further embodiment is a semiconductor device structure. The structure includes a source/drain region comprising one or more semiconductor materials, and the source/drain region is disposed over a substrate portion. The structure further includes an insulating material disposed adjacent the substrate portion, a first spacer disposed on the insulating material adjacent the source/drain region, a second spacer disposed on the first spacer, a dielectric layer disposed on the first and second spacers adjacent the source/drain region, and a contact etch stop layer disposed on the dielectric layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method, comprising:
forming a fin structure over a substrate;
depositing one or more spacers on a portion of the fin structure, wherein the one or more spacers are deposited on sidewalls of the fin structure;
removing a first portion of the one or more spacers to expose the fin structure;
recessing the fin structure, wherein a first byproduct layer is formed on a second portion of the one or more spacers;
passivating the first byproduct layer;
softening the first byproduct layer;
removing a portion of the first byproduct layer to expose the recessed fin structure; and
further recessing the fin structure.

2. The method of claim 1, wherein the first byproduct layer comprises an oxide prior to the passivating of the first byproduct layer.

3. The method of claim 2, wherein the passivating of the first byproduct layer comprises exposing the first byproduct layer to a nitrogen-containing plasma or an oxygen-containing plasma.

4. The method of claim 3, wherein the first byproduct layer is converted to a nitride layer after the passivating of the first byproduct layer.

5. The method of claim 1, wherein the softening of the first byproduct layer comprises exposing the first byproduct layer to a hydrogen-containing plasma.

6. The method of claim 1, wherein further recessing of the fin structure removes the first byproduct layer formed on the second portion of the one or more spacers.

7. The method of claim 6, wherein further recessing of the fin structure recesses the second portion of the one or more spacers.

8. The method of claim 7, wherein further recessing of the fin structure forms a second byproduct layer on the recessed second portion of the one or more spacers.

9. The method of claim 8, further comprising passivating and softening the second byproduct layer.

10. The method of claim 9, wherein a bias power of the passivating of the second byproduct layer is greater than a bias power of the passivating of the first byproduct layer.

11. The method of claim 9, wherein a bias power of the softening of the second byproduct layer is greater than a bias power of the softening of the first byproduct layer.

12. A method, comprising:
forming a fin structure over a substrate;
depositing one or more spacers on a portion of the fin structure, wherein the one or more spacers are deposited on sidewalls of the fin structure;
removing a first portion of the one or more spacers to expose the fin structure;
recessing the fin structure to expose a substrate portion, wherein a second portion of the one or more spacers located on a sidewall of the fin structure is recessed;
selectively depositing a dielectric layer on the recessed second portion of the one or more spacers; and
depositing a semiconductor material on the substrate portion.

13. The method of claim 12, wherein the selectively depositing of the dielectric layer comprises a cyclic process.

14. The method of claim 13, wherein the cyclic process comprises a deposition process, a treatment process, and a thermal process.

15. The method of claim 14, wherein the deposition process deposits a layer, and the treatment process causes molecules of the layer to cross-link.

16. The method of claim 13, wherein the selectively depositing of the dielectric layer further comprises a trimming process to remove portions of the dielectric layer formed on semiconductor materials and on vertical surfaces of dielectric materials.

17. A semiconductor device structure, comprising:
a source/drain region comprising one or more semiconductor materials, wherein the source/drain region is disposed over a substrate portion;
an insulating material disposed adjacent the substrate portion;
a first spacer disposed on the insulating material adjacent the source/drain region;
a second spacer disposed on the first spacer;
a dielectric layer disposed on the first and second spacers adjacent the source/drain region; and
a contact etch stop layer disposed on the dielectric layer.

18. The semiconductor device structure of claim 17, wherein the first and second spacers and the dielectric layer comprise Si, N, O, and C.

19. The semiconductor device structure of claim 18, wherein compositions of the first and second spacers and the dielectric layer are different.

20. The semiconductor device structure of claim 17, wherein the dielectric layer is disposed between the contact etch stop layer and the insulating material.
